(19) United States
(12) Patent Application Publication
(10) Pub. No.: US 2026/0023130 A1
(43) Pub. Date: Jan. 22, 2026

(54) MODEL PREDICTIVE CONTROL MITIGATION FOR BATTERY GAS GENERATION

(71) Applicant: Ford Global Technologies, LLC, Dearborn, MI (US)

(72) Inventors: Enhui Liu, Ann Arbor, MI (US); Jingmei Shen, Troy, MI (US); Fan Wang, Downers Grove, IL (US); Kevin Vander Laan, Bloomfield Hills, MI (US); Stefan Pototschnik, Canton, MI (US); Deborah E. Callicoat, Livonia, MI (US); Christian Shaffer, Canton, MI (US)

(21) Appl. No.: 18/778,501

(22) Filed: Jul. 19, 2024

(51) Int. Cl. G01R 31/392; B60L 58/16; B60L 58/25; G01R 31/36; G01R 31/367

(52) U.S. Cl. CPC G01R 31/392; B60L 58/16; B60L 58/25; G01R 31/3648; G01R 31/367

(57) ABSTRACT

Systems and methods for operating a vehicle that includes a traction battery are described. In one example, model predictive control is applied to estimate gas generated via the traction battery at a time in the future so that mitigating actions may be invoked before the traction battery may produce more gas than may be desired.

### FIELD

The present description relates to a model predictive control mitigation strategy for a battery. The battery may be a traction battery for an electric or hybrid vehicle.

### BACKGROUND

A hybrid or electric vehicle may include a traction battery that may supply electric energy to propel a vehicle. Li-ion batteries may have a characteristic of gassing where cells in the Li-ion battery may generate gas (e.g., H₂, CO₂, and CO). The gas formation may be indicative of electrolyte decomposition within Li-ion battery cells. Gas may be formed within battery cells over a life cycle of the battery and the gas may be vented from time t0 time. Generating gas within Li-ion battery cells may cause degraded performance and charge storage capacity of the battery.

The background above is provided to introduce in simplified form a selection of concepts that are further described in the detailed description. It is not meant to identify key features of the claimed subject matter, the scope of which is defined by the claims that follow the detailed description. Furthermore, the claimed subject matter is not limited to implementations that solve any disadvantages noted above or in any part of this disclosure.

### BRIEF DESCRIPTION OF THE DRAWINGS

The advantages described herein will be more fully understood by reading an example of an embodiment, referred to herein as the Detailed Description, when taken alone or with reference to the drawings, where:

FIG. 1 is a schematic diagram of an electric vehicle driveline that includes a traction battery;

FIG. 2 is a flowchart of an example method for controlling battery gassing and mitigating a possibility of generating more than a predetermined amount of gas with a battery;

FIG. 3 shows an example block diagram for model predictive control (MPC) of battery gassing; and

FIG. 4 shows a plot to illustrate how MPC for battery gassing may be initiated according to battery gas prediction;

FIG. 5 shows a plot that illustrates multi-stage MPC for battery gassing;

FIGS. 6 and 7 illustrate example control parameter trajectories during MPC for battery gassing.

### DETAILED DESCRIPTION

The present description is related to a method and system for controlling gassing within a battery over the life of the battery. The battery gassing may be mitigated during predetermined stages. The stages include different gassing thresholds that may be generated according to factors that may include but are not limited to vehicle performance, battery life expectations, and battery charging time.

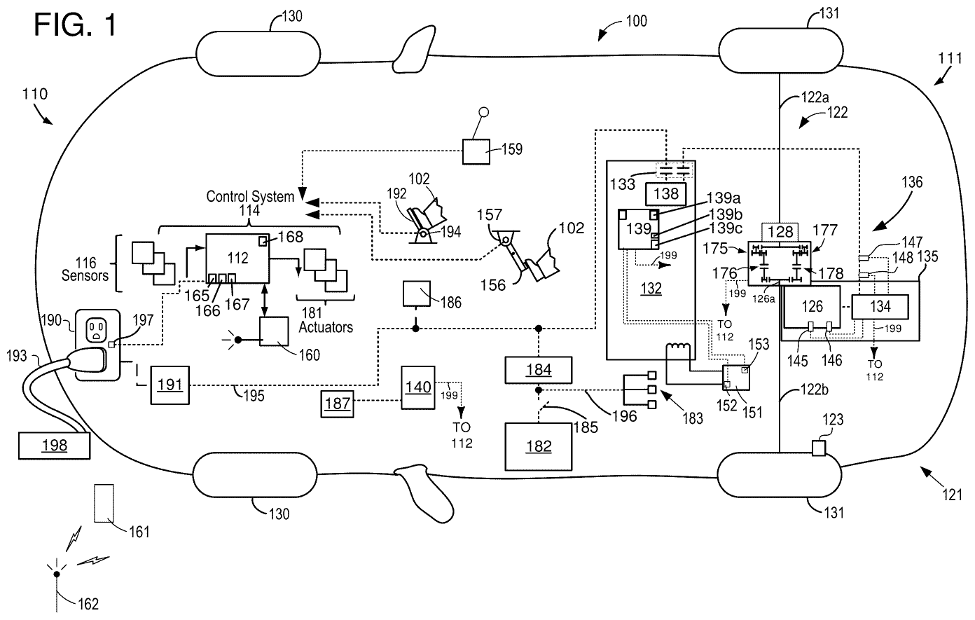

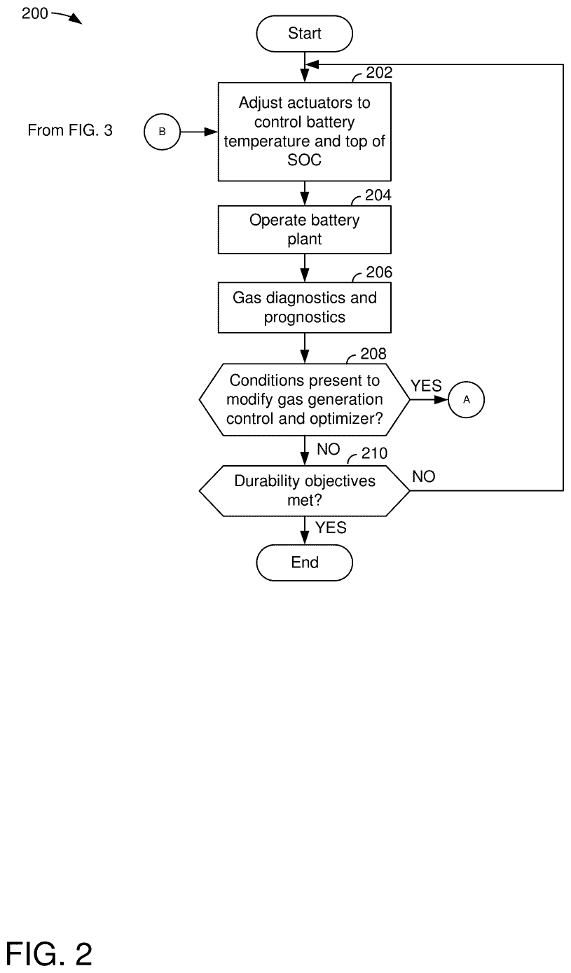

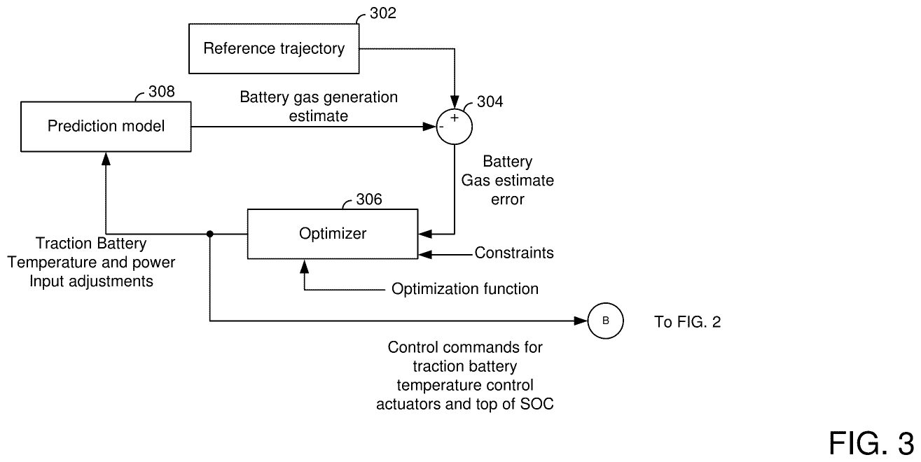

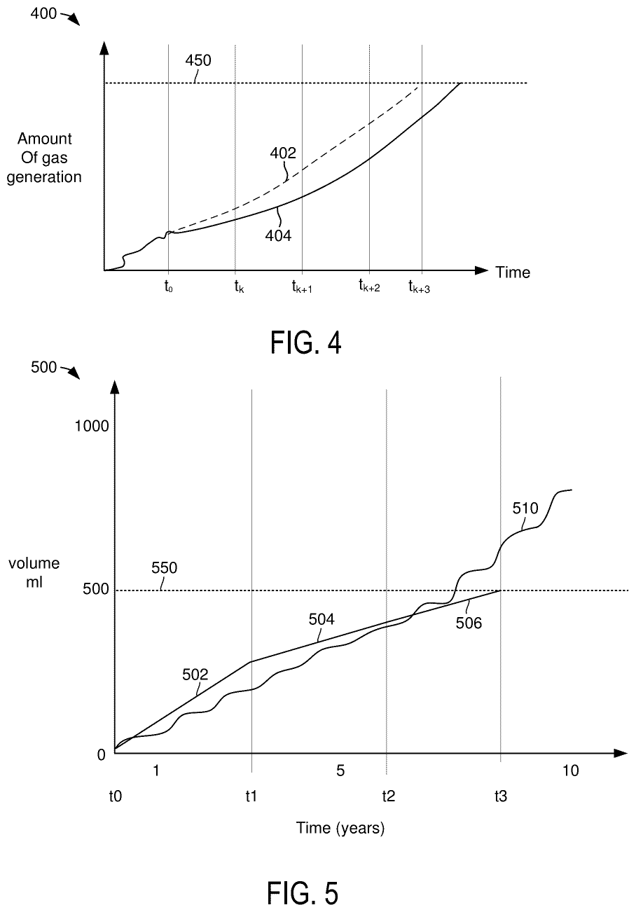

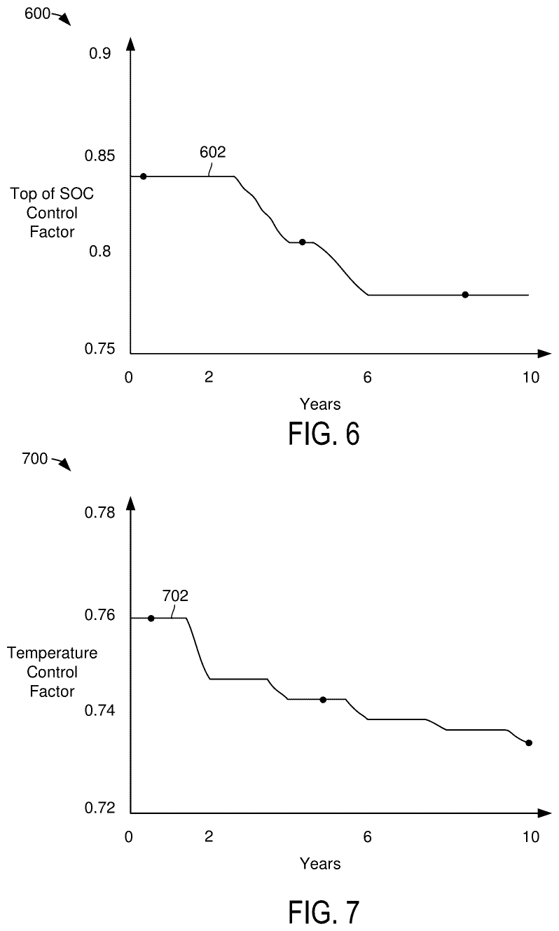

An example electric vehicle is shown in FIG. 1. An example method for controlling gassing of a Li-ion battery is shown in FIG. 2. A block diagram illustrating MPC for battery gassing is shown in FIG. 3. A plot illustrating when MPC is executed for a Li-ion battery is shown in FIG. 4. An illustration of multiple stages in a battery gassing control strategy is shown in FIG. 5. Variables for controlling gassing of a Li-ion battery are shown in FIGS. 6 and 7.

Electric vehicles and hybrid vehicles may include a Li-ion traction battery that supplies a traction motor with electric power. The Li-ion battery may generate gas at different rates according to environmental conditions and how the battery is being applied. For example, if a vehicle's driver is causing relatively large amounts of current to enter and exit the battery frequently, the battery may tend to generate additional gas. Further, if the battery is operated at temperatures that deviate from a prescribed temperature range, then the battery may tend to generate larger amounts of gas. If the battery is permitted to generate larger amounts of gas without constraints, the life span of the battery may be reduced.

The inventors herein have recognized the above-mentioned disadvantages and have developed a method for operating a battery, comprising: via one or more controllers, estimating an amount of gas generated via the battery according to battery operating conditions collected and stored to memory of the one or more controllers, where the amount of gas generated is predicted to be generated at a future time; adjusting one or more battery control parameters via the one or more controllers in response to the amount of gas generated; and adjusting one or more actuators in response to the one or more battery control parameters.

By predicting an amount gas that is expected to be generated via a traction battery at a future time, it may be possible to provide the technical result of controlling traction battery gas generation so that the traction battery meets life cycle expectations. For example, if a vehicle driver is operating the vehicle such that relatively large amounts of power are frequently being sourced and sunk by the traction battery, the traction battery may be prone to generating larger amounts of gas, which may affect the traction battery's life span. If the traction battery is predicted to produce larger amounts of gas, mitigating actions may be taken preemptively to extend the traction battery's life span.

The present description may provide several advantages. In particular, the approach may allow a traction battery to meet battery life span objectives. Further, the approach may take prior traction battery performance and longevity into consideration so that control adjustments may have higher probability of achieving their expected results. In addition, considering stages of a traction battery's life cycle may allow the present method to increase a likelihood of meeting user expectations and manufacturer's traction battery durability objectives.

The above advantages and other advantages, and features of the present description will be readily apparent from the following Detailed Description when taken alone or in connection with the accompanying drawings.

FIG. 1 is a block diagram of an example vehicle propulsion system 100 for vehicle 121. A front portion of vehicle 121 is indicated at 110 and a rear portion of vehicle 121 is indicated at 111. Vehicle propulsion system 100 includes electric machine 126. Electric machine 126 may consume or generate electrical power depending on its operating mode. Throughout FIG. 1, mechanical connections between various components are illustrated as solid lines, whereas electrical connections between various components are illustrated as dashed lines.

Vehicle propulsion system 100 has a rear axle 122. In some examples, rear axle 122 may comprise two half shafts, for example first half shaft 122a, and second half shaft 122b. Vehicle propulsion system 100 further has front wheels 130 and rear wheels 131. Rear wheels 131 may be driven via electric machine 126.

The rear axle 122 is coupled to electric machine 126. Rear drive unit 136 may transfer power from electric machine 126 to axle 122 resulting in rotation of rear wheels 131. Rear drive unit 136 may include a low gear 175 and a high gear 177 that are coupled to electric machine 126 via output shaft 126a of electric machine 126. Low gear 175 may be engaged via fully closing low gear clutch 176. High gear 177 may be engaged via fully closing high gear clutch 178. High gear clutch 178 and low gear clutch 176 may be opened and closed via commands received by rear drive unit 136 over controller area network (CAN) 199. Alternatively, high gear clutch 178 and low gear clutch 176 may be opened and closed via digital outputs or pulse widths provided via control system 114. Rear drive unit 136 may include differential 128 so that torque may be provided to first half shaft 122a and to second half shaft 122b. In some examples, an electrically controlled differential clutch (not shown) may be included in rear drive unit 136.

Electric machine 126 may receive electrical power from onboard electrical energy storage device (e.g. a Li-ion traction battery) 132. Furthermore, electric machine 126 may provide a generator function to convert the vehicle's kinetic energy into electrical energy, where the electrical energy may be stored at electric energy storage device 132 for later use by electric machine 126. An inverter system controller 134 (ISC1) may convert alternating current generated by electric machine 126 to direct current for storage at the electric energy storage device 132 and vice versa. Electric drive system 135 includes electric machine 126 and inverter system controller 134. Electric energy storage device 132 may be a battery, capacitor, inductor, or other electric energy storage device. Electric power flowing into electric drive system 135 may be monitored via current sensor 145 and voltage sensor 146. Position and speed of electric machine 126 may be monitored via position sensor 147. Torque generated by electric machine 126 may be monitored via torque sensor 148.

Electric machine 126 may propel vehicle 121 in a forward direction or reverse direction in response a position of shift selector 159. Further, vehicle 121 may enter park (e.g., no vehicle movement with vehicle wheels locked in a stationary position) or neutral in response to a position of shift selector 159.

In some examples, electric energy storage device 132 may be configured to store electrical energy that may be supplied via a high voltage bus 195 (e.g., components such as conductors that carry electric current and high voltage (e.g., voltage greater than 300 volts). High voltage bus 195 may be in electrical communication with high voltage vehicle accessories (e.g., heat pump, air conditioner, heater, etc.) 186 and power converter 191 (e.g., direct current (DC) to DC converter or alternating current (AC) to DC converter). Power converter 191 is electrically coupled to electrical receptacle 190 and electrical receptacle 190 may be electrically coupled to an external stationary electric power grid 198 (e.g., a charging station) via cord 193. Receptacle sensor 197 provides an indication of whether or not vehicle 121 is plugged in to the stationary electric power grid 198. Stationary electric power grid 198 resides external to the vehicle (e.g., not part of the vehicle). High voltage bus 195 may also be electrically coupled to bidirectional DC/DC converter 184, which allows electric power to be transferred from high voltage bus 195 to low voltage bus 196 (e.g., conductors, terminals, and other conductive linking devices). Thus, electric power may be exchanged between electric energy storage device 132 and low voltage battery 182 (e.g., battery voltage of less than 20 volts). Switch 185 may be selectively opened to prevent power to low voltage battery 182 (e.g., 12 volts DC) from low voltage bus 196. Low voltage bus 196 may distribute low voltage electric power to low voltage electric loads 183 (e.g., electric power consumers such as infotainment system, windshield wipers, power bolster, blowers, etc.). FIG. 2 provides a more detailed view of the vehicle's power distribution system.

Electric energy storage device 132 includes an electric energy storage device controller 139 and a power distribution module 138. Electric energy storage device controller 139 may provide charge balancing between energy storage element (e.g., battery cells) and communication with other vehicle controllers (e.g., controller 112). Electric energy storage device controller 139 includes a microcontroller 139a, random-access memory 139b, non-transitory memory 139c, and inputs and outputs 139d. Electric energy storage device controller 139 may communicate with other controllers via CAN 199. Power distribution module 138 controls flow of power into and out of electric energy storage device 132. A contactor 133 may selectively couple and decouple electric energy storage device 132 to high voltage bus 195 and inverter system controller (ISC1) 134. In some examples, contactor 133 may be located external to the electric energy storage device 132.

Electric energy storage device temperature control system 151 may selectively cool or warm electric energy storage device 132. Valve 152 may control flow of coolant through (system 151, thereby controlling a temperature of electric energy storage device 132. Electric energy storage device temperature control system 151 may also include a fan 153 to control a temperature of electric energy storage device 132. In one example, electric energy storage device temperature control system 151 may be configured as a heat pump.

Control system 114 may communicate with electric machine 126, energy storage device 132, navigation system 187, etc. Control system 114 may receive sensory feedback information from electric drive system 135 and electric energy storage device 132, etc. Further, control system 114 may send control signals to electric drive system 135 and electric energy storage device 132, etc., responsive to this sensory feedback. Control system 114 may receive an indication of an operator requested output of the vehicle propulsion system from a human operator 102, or an autonomous controller. For example, control system 114 may receive sensory feedback from pedal position sensor 194 which communicates with pedal 192. Pedal 192 may refer schematically to a driver demand pedal. Similarly, control system 114 may receive an indication of an operator (e.g., user) requested vehicle slowing via a human operator 102, or an autonomous controller. For example, control system 114 may receive sensory feedback from pedal position sensor 157 which communicates with vehicle slowing pedal 156.

One or more wheel speed sensors (WSS) 123 may be coupled to one or more wheels of vehicle propulsion system 100. The wheel speed sensors may detect rotational speed of each wheel. Such an example of a WSS may include a permanent magnet type of sensor.

Controller 112 may comprise a portion of a control system 114. In some examples, controller 112 may be a single controller of the vehicle. Control system 114 is shown receiving information from a plurality of sensors 116 (various examples of which are described herein) and sending control signals to a plurality of actuators 181 (various examples of which are described herein). As one example, sensors 116 may include tire pressure sensor(s) (not shown), wheel speed sensor(s) 123, etc. In some examples, sensors associated with electric machine 126, wheel speed sensor 123, etc., may communicate information to controller 112, regarding various states of electric machine operation. Controller 112 includes non-transitory (e.g., read exclusive memory) 165, random access memory 166, digital inputs/outputs 168, and a microcontroller 167. Controller 112 may receive input data and provide data to human/machine interface 140 via CAN 199.

Additionally, controller 112 may send vehicle data and receive command instructions (e.g. a request to prepare the vehicle for extended storage) via transceiver 160 and remote device 161 (e.g., cell phone, tablet, or other remote wireless device). Remote device 161 may transmit commands and receive data via cellular or satellite network 162.

The system of FIG. 1 provides for a system, comprising: a traction battery; and one or more controllers including executable instructions stored in non-transitory memory that cause the one or more controllers to conditionally execute a control parameter adjustment routine for the traction battery in response to a comparison between an estimate of gas produced via the traction battery and a threshold gas amount. In a second example that may include the first example, the system includes where the control parameter adjustment routine predicts an amount of gas generated via the traction battery. In a third example that may include one or both of the first and second examples, the system includes where the control parameter adjustment routine predicts the amount of gas generated via the traction battery according to a model. In a fourth example that may include one or more of the first through third examples, the system includes where the model predicts the amount of gas generated via the traction battery one predetermined time interval ahead of a present time. In a fifth example that may include one or more of the first through fourth examples, the system further comprises additional executable instructions that cause the one or more controllers to adjust one or more actuators in response to output of the control parameter adjustment routine. In a sixth example that may include one or more of the first through fifth examples, the system includes where the threshold gas amount is divided into two or more segments. In a seventh example that may include one or more of the first through sixth examples, the system includes where the threshold gas amount in at least one of the two or more segments is based on an amount of gas generated according to vehicle performance metrics.

Referring now to FIG. 2, a flowchart of a method of controlling battery gassing and mitigating a possibility of generating more than a threshold amount of gas is shown. The method of FIG. 2 may be incorporated into one or more controllers (e.g., 139) of the system shown in FIG. 1 as executable instructions stored in non-transitory memory. The flowchart of FIG. 2 may be executed at predetermined time intervals (e.g., between once a week and once a day).

At 202, method 200 adjusts one or more actuators to control battery temperature and a top SOC level. The actuator that controls traction battery top of SOC may be an electric energy storage device controller, an inverter or other device that may supply power to the high voltage bus or consume power from the high voltage bus. The actuator that controls traction battery temperature may be a fan and/or a value.

Initially, when the vehicle is first manufactured, a base battery temperature range and a base top level SOC (e.g., a maximum SOC level that the battery may be charged to, such as 100% SOC) are stored to controller memory. The base battery temperature range may be adjusted via a temperature control factor that provides compensation for battery gassing (e.g., a battery temperature may be adjusted to a temperature Bat_set=Bat_temp_base*û_{T,opt}, where Bat_set is the requested battery temperature, Bat_temp_base is a baseline battery temperature, and û_{T,opt} is a battery temperature control factor for battery gassing) and the battery may be controlled to the modified base battery temperature via one or more actuators. Similarly, the base top level SOC may be adjusted via a top of SOC control factor that provides compensation for battery gassing (e.g., a battery top SOC may be adjusted to a SOC Bat_SOC_top=Bat_SOC_top_base*û_{DoD,opt}, where Bat_SOC_set is the requested top battery SOC, Bat_SOC_top_base is a baseline top battery SOC, and û_{DOD,opt} is a top battery SOC temperature control factor for battery gassing) and the battery may be controlled to the modified base top level SOC via one or more actuators.

At 204, method 200 operates the traction battery. The traction battery is operated according to the requested battery temperature and the requested top SOC as well as driver demand torque or power. For example, method 200 may constrain SOC to be less than the requested top battery SOC and battery temperature to be the requested battery temperature when the traction battery is delivering power to meet the driver demand torque. Method 200 proceeds to 206.

At 206, method 200 performs battery gas diagnostics and prognostics. In one example, method 200 may predict battery gas according to the following equations:

$$V ( t + 1 ) = V ( t ) + \frac{dv ( t )}{dt} * dt \qquad ( 1 )$$

$$\frac{dv ( t )}{dt} = ( 1 + CIA ) * k * {V}^{( ( {exp}_{t - 1} ) {exp}_{t} )} ( t ) \qquad ( 2 )$$

$$k = {exp}_{t} * {( pref * exp ( - \frac{{E}_{T}}{R * {T}_{k}} ) * exp ( {pref}_{SOC} * SOC ) )}^{1 / {exp}_{t}} \qquad ( 3 )$$

$$CIA = {pref}_{{CIA}_{tan} * tan ( {pref}_{{DoD}_{tan}} * {\hat{u}}_{DoD} * DoD ) * {cycle}^{( {exp}_{cycle} )}} \qquad ( 4 )$$

$${T}_{K} = {\hat{u}}_{T} * ( {T}_{c} + 273.15 ) \qquad ( 5 )$$

where V(t+1) is a volume of gas one time interval ahead of the present time, V(t) is the volume of gas generation by the battery at a present time, cycle is the cycle number of the battery (e.g., an actual total number of discharge/charge cycles), T_{c} is battery cell temperature, SOC is battery state of charge, DoD is depth of discharge of the battery ranging from values between 0 and 1, expₜ, exp_{cycle}, pref, pref_{CIAtan}, pref_{DoDtan}, and pref_{SOC} are calibratable (e.g., adjustable) values that may be determined via repeatedly charging and discharging a battery while monitoring gassing), Er and R are universal constants, û_{T}=û_{T,opt}, and û_{DOD}=û_{DoD,opt}. Equations 1-5 represent one example battery gassing model, but other battery gassing models may be applied without departing from the scope or intent of the present disclosure.

Method 200 may also measure an amount of gas that is presently in battery cells of the traction battery via converting pressure in battery cells to an amount of gas in the battery cells. Alternatively, method may infer an amount of gas that is presently in battery cells of the traction battery by measuring a size of battery cells within the traction battery and converting battery cell size to an amount of gas via an empirically determined function that relates battery cell volume to an amount of gas within a battery cell. Method 200 proceeds to 208 after predicting battery gas amounts in the future and determining a present amount of gas within the traction battery.

At 208, method 200 judges whether or not the predicted battery gas trajectory is greater than a control target for battery gas generation and greater than a battery gas generation threshold. The battery gas threshold and/or battery gas target may be divided into predetermined stages as shown in FIG. 5. The control target for battery gas generation may be based on gas levels of similar traction batteries that have met battery durability and use metrics. The battery gas threshold may be equal to the control target for battery gas generation plus an offset value, where the offset value may be zero or greater than zero. The control target for battery gas generation may be stored in controller memory. If method 200 judges that the predicted battery gas trajectory is greater than the control target value and the battery gas generation threshold value, the answer is yes and method 200 proceeds to execute the MPC shown in FIG. 3. Otherwise, the answer is no and method 200 proceeds to 210. This step allows the control parameter optimization to be performed when appropriate so that computational time and power may be conserved. The control target for battery gas generation may also be referred to as a requested battery gas generation amount.

At 210, method 200 judges whether or not durability objectives for the traction battery have been met. The durability objectives may include one or more of the battery being in use for a predetermined amount of time, the battery experiencing a threshold number of charging and discharging cycles, etc. If method 200 judges that the traction battery has met durability objectives, the answer is yes and method 200 proceeds to exit. Otherwise, the answer is no and method 200 returns to 202.

In this way, a traction battery may be operated and gas generation within the battery may be controlled. The traction battery mitigation may be performed according to time and traction battery operating conditions. If gas generation within the traction battery is greater than may be desired, cooling of the traction battery may be adjusted and the top SOC may be reduced so as to reduce a possibility of gas generation within the traction battery.

Referring now to FIG. 3, a block diagram of model predictive control (MPC) for a traction battery is shown. The MPC of FIG. 3 may be activated at select times and/or conditions so that computational loading for predicting gassing within the traction battery and optimizing control parameters for controlling battery gassing may be reduced while gassing within the battery follows a requested trajectory. The MPC of FIG. 3 may be generated via executable instructions stored in controller memory.

At block 302, a traction battery gassing trajectory (e.g., historical traction battery data) is input to the MPC. The traction battery gassing trajectory describes a desired or requested amount of battery gas that is generated over a period of time (e.g., 10 years), and this trajectory is stored to controller memory (e.g., read-exclusive memory). The traction battery gassing trajectory may be based on data that is collected via operating one or more different traction batteries in vehicles or on a test rig. The traction battery gassing trajectory may be input in the form of a data vector, and the data vector may be stored in controller memory. The traction battery gassing trajectory is input to summing junction 304.

At summing junction 304, output of a prediction model 308 (e.g., an amount of gas that is generated via the traction battery) is input to a negative input of summing junction so that output of the prediction model is subtracted from output of the reference trajectory to generate a traction battery gassing error amount. The traction battery gassing error amount is input to block 306.

At block 306, an optimizer generates control requests û for the top of SOC control for the traction battery and for battery temperature control factor for battery gassing. The optimizer receives an optimization function and constraints to determine the control requests û=[û_{DOD}, û_{T}]. In one example, the constraint is where û is between a value of 0 and a value of one and the optimization function is:

$$J = α * {sum ( {V}_{prediction , {t}_{future}} - {V}_{reference , {t}_{future}} )}^{2} + b * {( {\hat{u}}_{future} - {\hat{u}}_{last} )}^{2}$$

where a and b are hyper parameters, V_{prediction,t}_{_{future}} is predicted gas volume from the traction battery at a later time t based on historical data (e.g., battery temperature T, battery power trajectories, traction battery SOC, and DoD values) from a traction battery as output from prediction model 308, and where V_{reference,t}_{_{future}} is a requested or target traction battery gas volume at a predetermined time t in the future as output from block 302. The first term of J seeks to control û so that the traction battery gas prediction converges to a gas generation target at time t_{future}. The second term of J seeks to ensure that the control variables [û_{DOD}, û_{T}] change smoothly.

The optimizer iteratively adjusts the control variables [û_{DOD}, û_{T}] so that the output of J converges to a specified value or within a range of values. Once the control variables are determined that cause the output of J to converge to the specified value, [û_{DOD}, û_{T}] are stored to controller random-access memory as ûₒₚₜ=[û_{DoD,opt}û_{T,opt}]. These values may be returned to step 202 of FIG. 2 where they may be applied to control traction battery top of SOC and traction battery temperature.

At 308, the MPC control predicts battery gassing. The MPC control may predict battery gassing via equations 1-5 as described at step 206 of FIG. 2 according to the control variables [û_{DOD}, û_{T}] that are output via the optimizer at 306. The prediction model outputs the predicted gas volume to summing junction 304.

Thus, the method of FIGS. 2 and 3 provides for a method for operating a battery, comprising: via one or more controllers, estimating an amount of gas generated via the battery according to battery operating conditions collected and stored to memory of the one or more controllers, where the amount of gas generated is predicted to be generated at a future time; adjusting one or more battery control parameters via the one or more controllers in response to the amount of gas generated; and adjusting one or more actuators in response to the one or more battery control parameters. In a first example, the method includes where the one or more actuators include a valve or a fan. In a second example that may include the first example, the method includes where the one or more battery control parameters include a top of state of charge battery control parameter and a battery temperature control parameter. In a third example that may include one or both of the first and second examples, the method further comprises generating the top of state of charge battery control parameter and the battery temperature control parameter via an iterative process. In a fourth example that may include one or more of the first through third examples, the method includes where the amount of gas generated at the future time via the battery is estimated via a gas generation model. In a fifth example that may include one or more of the first through fourth examples, the method includes where the gas generation model estimates the amount of gas generated at the future time one time interval ahead of a present time. In a sixth example that may include one or more of the first through fifth examples, the method includes where battery operating conditions collected and stored to memory of the one or more controllers are from a different battery. In a seventh example that may include one or more of the first through sixth examples, the method includes where the amount of gas generated at the future time is based on a derivative of gas generated.

The method of FIGS. 2 and 3 also provides for a method for operating a battery, comprising: via one or more controllers, estimating an amount of gas generated via the battery according to battery operating conditions collected and stored to memory of the one or more controllers, where the amount of gas generated is predicted to be generated at a future time; and adjusting one or more actuators via the one or more controllers in response to a threshold gas amount that includes at least two stages. In a first example, the method includes where the threshold gas amount changes in at least one of the at least two stages according to a level of vehicle performance. In a second example that may include the first example, the method includes where the threshold gas amount changes in at least one of the at least two stages according to a vehicle charging time (e.g. an amount of time it takes to charge a vehicle from its present charge level to a threshold level, such as 100%). In a third example that may include one or both of the first and second examples, the method further comprises comparing the amount of gas generated to the threshold gas amount. In a fourth example that may include one or more of the first through third examples, the method includes where the at least two stages have time based durations.

Referring now to FIG. 4, a plot 400 describing conditions for activating MPC for battery gassing is shown. The vertical lines represent time where conditions are evaluated for executing the MPC of FIG. 3 are shown. The vertical axis represents an amount of gas that is generated by the traction battery and the amount of gas increases in the direction of the vertical axis arrow. The horizontal axis represents time and time increases from the left side of the plot to the right side of the plot. The gas prediction begins at time t0 and it is evaluated at predetermined time instants tk. The time between time instants may be relatively long or short in duration. For example, the amount of time between battery gas evaluations may range between one month and one year. The trade-off for adjusting interval timing between MPC evaluations is that shorter times between intervals increases computational loading on the controller and longer time intervals between intervals may reduce the effectiveness of the MPC.

Horizontal line 450 represents a maximum threshold for gas that is generated via the traction battery over the life of the traction battery. Dashed line 402 represents a predicted amount of gas that is generated via the traction battery and solid line 404 represents a control target or desired control level for gas that is generated via the traction battery.

In this example, the predicted amount of gas that is generated via the traction battery as indicated by dashed line 402 is greater than the control target level for gas generation by the traction battery. Therefore, the control parameter adjustment routine that is represented via the block diagram in FIG. 3 may be executed so that traction battery gas generation may converge toward the control target level of gas generation.

Referring now to FIG. 5, a plot 500 describing a threshold traction battery gas generation amount as a function of time is shown. The vertical axis represents a cumulative volume amount of gas that has been generated via a traction battery. The cumulative volume amount increases from the horizontal axis in the direction of the vertical axis arrow. The horizontal axis represents time and time increases from the left side of the figure to the right side of the figure. Horizontal dashed line 550 represents an actual total cumulative amount gas threshold that represents an actual total amount of gas that may be generated via the traction battery over the course of the traction battery's life span.

In this example, a target control gas amount (a cumulative amount of gas generated by the traction battery) is broken into three stages or segments. However, it may be appreciated that the target control gas amount may be broken into more or fewer stages. The first stage is represented by line 502 and it extends between time t0 and time t1. The second stage is represented by line 504 and it extends between time t1 and time t2. The third state is represented by line 506 and it extends between time t2 and time t3.

Each of the target control gas amounts in the stages seeks to balance a vehicle operator's driving experience (e.g., vehicle performance including rate of vehicle speed increase/decrease, maximum motor torque generation, amount of time it takes to recharge the traction battery, depth of traction battery discharge, vehicle driving range, etc.) and the traction battery's gas generation rate. In the first stage (e.g., first three years of vehicle operation for this example), the slope of line 502 is greater to allow for larger amounts of gas generation as compared to the second and third stages. The larger rate of gas generation for the first stage is based on expectations that the vehicle user values performance, shorter charging times, driving range, and wheel torque over battery longevity. In the second stage (e.g., second three years of vehicle operation for this example), the slope of line 504 is less than the slope of line 502 and greater than the slope of line 506 to allow for medium amounts of gas generation as compared to the first and third stages. The medium rate of gas generation for the second stage is based on expectations that the vehicle user still places some value on performance, shorter charging times, driving range, and wheel torque, but wishes for battery longevity. In the third stage (e.g., third three years of vehicle operation for this example), the slope of line 506 is less than the slope of line 502 and less than the slope of line 504 to allow for lower amounts of gas generation as compared to the first and second stages. The lower rate of gas generation for the third stage is based on expectations that the vehicle user still places somewhat less value on performance, shorter charging times, driving range, and wheel torque as compared to battery longevity.

Battery operating conditions may be adjusted so that the battery's gas production tends to be less than or follow that of lines 502, 504, and 506 that make up the target gas generation amount. For example, the top SOC for the traction battery may be lowered to reduce battery gas generation and the battery temperature may be adjusted into a predetermined range to reduce battery gas generation.

Referring now to FIG. 6, a plot 600 showing how a top of SOC control factor may be adjusted over a life span of a traction battery is shown. The vertical axis represents a value of a top of SOC control factor for adjusting an amount of gas that is generated by the traction battery is shown. The amount of the top of SOC control factor increases in the direction of the vertical axis arrow. The horizontal axis represents time and time increases from the left side of the plot to the right side of the plot. Trace 602 represents the top of SOC control factor value with respect to time.

In this example, the top of SOC control factor starts off at a higher value and as time increases, the top of SOC control factor value is stepped downward a little after two years have passed. The top of SOC control factor steps down a second time near the five year mark. The stepdown locations show where the control parameter adjustment routine is executed to update the control parameters (e.g., û_{DOD,opt}û_{T,opt}).

Referring now to FIG. 7, a plot 700 showing how a traction battery temperature control factor may be adjusted over a life span of a traction battery is shown. The vertical axis represents a traction battery temperature control factor for adjusting an amount of gas that is generated by the traction battery is shown. The amount of the traction battery temperature control factor increases in the direction of the vertical axis arrow. The horizontal axis represents time and time increases from the left side of the plot to the right side of the plot. Trace 702 represents the traction battery temperature control factor value with respect to time.

In this example, the traction battery temperature control factor starts off at a higher value and as time increases, the traction battery temperature control factor value is stepped downward a shortly before two years have passed. The traction battery temperature control factor steps down several times over the traction battery's life span. The stepdown locations show where the control parameter adjustment routine is executed to update the control parameters (e.g., û_{DoD,opt}û_{T,opt}).

Note that the example control and estimation routines included herein can be used with various vehicle system configurations. The control methods and routines disclosed herein may be stored as executable instructions in non-transitory memory and may be carried out by the control system including one or more controllers in combination with the various sensors, actuators, and other engine hardware. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the example embodiments described herein, but is provided for ease of illustration and description. One or more of the illustrated actions, operations and/or functions may be repeatedly performed depending on the particular strategy being used. Further, at least a portion of the described actions, operations and/or functions may graphically represent code to be programmed into non-transitory memory of the computer readable storage medium in the control system. The control actions may also transform the operating state of one or more sensors or actuators in the physical world when the described actions are carried out by executing the instructions in a system including the various engine hardware components in combination with one or more controllers.

This concludes the description. The reading of it by those skilled in the art would bring to mind many alterations and modifications without departing from the spirit and the scope of the description. For example, an anticipated low voltage battery replacement procedure may combine steps shown herein, have fewer steps than are shown herein, or have additional steps than are shown herein without departing from the scope or intent of the present description. Further, the approach may be applied to front drive vehicles, rear drive vehicles, four-wheel drive vehicles, and hybrid vehicles without departing from the scope or intent of the present disclosure. Further, it is anticipated that controller arrangements and electrical component arrangements may deviate from those shown herein without departing from the scope or intent of this disclosure.

1. A method for operating a battery, comprising:
via one or more controllers, estimating an amount of gas generated via the battery according to battery operating conditions collected and stored to memory of the one or more controllers, where the amount of gas generated is predicted to be generated at a future time;
adjusting one or more battery control parameters via the one or more controllers in response to the amount of gas generated; and
adjusting one or more actuators in response to the one or more battery control parameters.

2. The method of claim 1, where the one or more actuators include a valve or a fan.

3. The method of claim 1, where the one or more battery control parameters include a top of state of charge battery control parameter and a battery temperature control parameter.

4. The method of claim 3, further comprising generating the top of state of charge battery control parameter and the battery temperature control parameter via an iterative process.

5. The method of claim 1, where the amount of gas generated at the future time via the battery is estimated via a gas generation model.

6. The method of claim 5, where the gas generation model estimates the amount of gas generated at the future time one time interval ahead of a present time.

7. The method of claim 1, where battery operating conditions collected and stored to memory of the one or more controllers are from a different battery.

8. The method of claim 1, where the amount of gas generated at the future time is based on a derivative of gas generated.

9. A system, comprising:
a traction battery; and
one or more controllers including executable instructions stored in non-transitory memory that cause the one or more controllers to conditionally execute a control parameter adjustment routine for the traction battery in response to a comparison between an estimate of gas produced via the traction battery and a threshold gas amount.

10. The system of claim 9, where the control parameter adjustment routine predicts an amount of gas generated via the traction battery.

11. The system of claim 10, where the control parameter adjustment routine predicts the amount of gas generated via the traction battery according to a model.

12. The system of claim 11, where the model predicts the amount of gas generated via the traction battery one predetermined time interval ahead of a present time.

13. The system of claim 9, further comprising additional executable instructions that cause the one or more controllers to adjust one or more actuators in response to output of the control parameter adjustment routine.

14. The system of claim 9, where the threshold gas amount is divided into two or more segments.

15. The system of claim 14, where the threshold gas amount in at least one of the two or more segments is based on an amount of gas generated according to vehicle performance metrics.

16. A method for operating a battery, comprising:
via one or more controllers, estimating an amount of gas generated via the battery according to battery operating conditions collected and stored to memory of the one or more controllers, where the amount of gas generated is predicted to be generated at a future time; and
adjusting one or more actuators via the one or more controllers in response to a threshold gas amount that includes at least two stages.

17. The method of claim 16, where the threshold gas amount changes in at least one of the at least two stages according to a level of vehicle performance.

18. The method of claim 16, where the threshold gas amount changes in at least one of the at least two stages according to a vehicle charging time.

19. The method of claim 16, further comprising comparing the amount of gas generated to the threshold gas amount.

20. The method of claim 16, where the at least two stages have time based durations.
